(19) United States
(12) Patent Application Publication
(10) Pub. No.: US 2025/0159921 A1
(43) Pub. Date: May 15, 2025

(54) NON-VOLATILE FIELD-EFFECT TRANSISTOR BASED ON A TWO-DIMENSIONAL ELECTRON GAS

(71) Applicants: COMMISSARIAT À L'ÉNERGIE ATOMIQUE ET AUX ÉNERGIES ALTERNATIVES, Paris (FR); CENTRE NATIONAL DE LA RECHERCHE SCIENTIFIQUE, Paris (FR); UNIVERSITE GRENOBLE ALPES, Saint Martin D'Heres (FR)

(72) Inventors: Cécile GREZES, Grenoble Cedex 9 (FR); Jean-Philippe ATTANE, Grenoble Cedex 9 (FR); Manuel BIBES, Palaiseau (FR); Laurent VILA, Grenoble Cedex 9 (FR)

(73) Assignees: COMMISSARIAT À L'ÉNERGIE ATOMIQUE ET AUX ÉNERGIES ALTERNATIVES, Paris (FR); CENTRE NATIONAL DE LA RECHERCHE SCIENTIFIQUE, Paris (FR); UNIVERSITE GRENOBLE ALPES, Saint Martin D'Heres (FR)

(21) Appl. No.: 18/834,270

(22) PCT Filed: Feb. 1, 2023
(86) PCT No.: PCT/EP2023/052391

§ 371 Date: Jul. 30, 2024

(30) Foreign Application Priority Data
Feb. 2, 2022 (FR) FR2200906

(51) Int. Cl. H10D 30/47; H10D 64/68; H10N 70/20

(52) U.S. Cl. CPC H10D 30/481; H10D 64/689; H10N 70/253

(57) ABSTRACT

A non-volatile field-effect transistor includes a gate electrode including a first contact, a source comprising a second contact, a drain including a third contact, a channel between the drain and the source and formed by a two-dimensional electron gas, a remanent-state subassembly having two electrically controllable remanent states comprising at least one oxide layer, and a reducing layer made of at least one metal-type reducing material having an atomic concentration of metal elements greater than 50%. The application of a voltage between the first contact and another contact results in a non-volatile modulation of the conductivity of the two-dimensional gas.

The present invention relates to a non-volatile field-effect transistor using a two-dimensional electron gas.

A field-effect transistor is often referred to by the abbreviation FET. Such a transistor is often used as a switch or as an amplifier.

A field-effect transistor is a unipolar three-terminal device with three terminals (drain, source and gate) relying on the action of an electric field on the conductivity of a channel located between the drain and the source. In the channel, the carriers, electrons or holes, are free to move between the source and the drain under the action of a voltage applied between said two terminals. The conductance of the channel is controlled by applying a voltage to the gate. Many types of field-effect transistors exist depending on the nature of the carrier (electron or hole) or the nature of the electrical control exerted on the channel.

Field-effect transistors are currently constructed using a variety of semiconductor materials, especially monocrystalline silicon materials. Other materials are used, however, such as amorphous silicon, polycrystalline silicon, gallium arsenide or gallium nitride.

In a FET transistor, a power supply maintains the on state (i.e. non-zero channel conductivity) or off state (zero channel conductivity) of the transistor, since the state depends on the voltage applied to the gate. Such state is volatile: if the power supply is interrupted, the voltage applied to the gate necessarily becomes zero, and the state is not preserved. Applying a voltage consistently to preserve the memory state results in power consumption to maintain the transistor state. Such consumption is called static because same is related to the occurrence of leakage currents, and not to the dynamic process of writing or reading the memory.

The creation of non-volatile field-effect transistors, thus apt to maintain the state of the transistor in the absence of power supply, eliminates static energy consumption and thus reduces energy consumption. Non-volatility can also make it possible to consider a transistor with additional functions, such as a memory function or a logic calculation function.

A plurality of non-volatile field-effect transistors have been proposed, based on semiconductor transistors. More particularly, work focuses on the development of the ferroelectric field-effect transistor, more often referred to as Fe-FET. The Fe-FET comprises a ferroelectric element between the gate and the drain-source channel serving to maintain the on or off state in the absence of power supply.

Known Fe-FET transistors suffer from limited endurance and from a contrast between the on and off states (sometimes referred to as “ON/OFF contrast”).

There is thus a need for a non-volatile transistor having a better endurance and improved contrast between the on state and the off state.

To this end, the description describes a non-volatile field-effect transistor, the transistor comprising a first electrode called the gate electrode including a first contact, a second electrode called the source electrode, the source comprising a second contact, a third electrode called the drain, the drain including a third contact, a channel between the drain and the source, the channel consisting of a two-dimensional electron gas, a remanent-state subassembly, the remanent-states subassembly having at least two electrically controllable remanent states, the remanent-state subassembly being in contact with the channel, the remanent-state subassembly including at least one oxide layer and a reducing layer made of at least one metal-type reducing material, each metal-type reducing material having an atomic concentration of metal elements greater than or equal to 50%. The first electrode is in contact with the remanent-state subassembly and the application of a voltage between the first contact and one of the second and third contacts results in a non-volatile modulation of the conductivity of the two-dimensional gas forming the channel.

The reducing layer makes it possible to create the two-dimensional gas of electrons forming the channel at the interface between the reducing layer and the remanent-state subassembly.

According to particular embodiments, the non-volatile transistor has one or a plurality of the following features, taken individually or according to all technically possible combinations:
the reducing layer serves to create the two-dimensional gas forming the channel at the interface between the reducing layer and the remanent-state subassembly.
the reducing layer is a monolayer of metal-type reducing material or a multilayer of metal-type reducing materials, the reducing material(s) each having an atomic concentration of metal elements greater than or equal to 50%.
the remanent-state subassembly comprises at least one non-volatile dielectric layer or multilayer electrically controlled, by the ferroelectric effect, by the trapped charge effect, by the ion migration effect or by a combination of a plurality of said effects.
each metal-type reducing material has an atomic concentration of metal elements greater than or equal to 80%.
each metal element is chosen from the list consisting of aluminum, tantalum, yttrium, magnesium and ruthenium.
the reducing layer has a thickness of less than or equal to 15 nanometers and preferably less than or equal to 10 nanometers.
the transistor includes a substrate on which rests the drain, the source and the reducing layer, the reducing layer, the channel and the remanent-state subassembly forming a stack in said order, and the first electrode rests on the remanent-state subassembly.
the remanent-state subassembly rests on the first electrode, the drain, the channel and the source rest on the remanent-state subassembly, and the reducing layer is arranged on the channel.
the non-volatile transistor further includes a protective layer over the reducing layer.
the remanent-state subassembly includes a layer chosen from a layer of oxide made of perovskite oxides, a layer of oxide made of (Hf₁₋ₓZrₓ)O₂, x varying between 0 and 1, doped if appropriate, and a layer made of poly (vinylidene fluoride).
the transistor includes a reading unit, the reading unit including a sub-unit for applying a voltage between the drain and the source and a sub-unit for measuring the current between the drain and the source.
the source and drain are in contact with the ends of the channel.

The features and advantages of the invention will appear upon reading the following description, given only as an example, but not limited to, and making reference to the enclosed drawings, wherein:

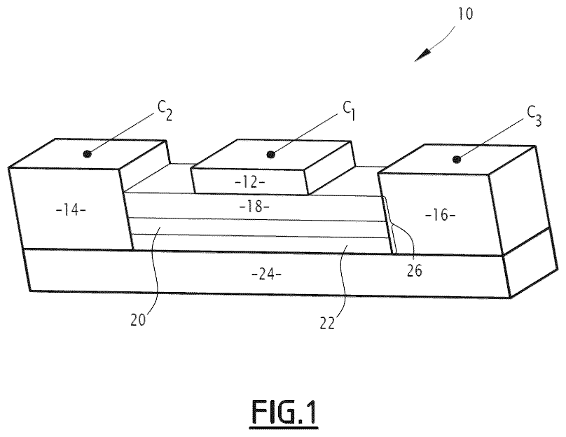

FIG. 1 is a schematic representation of an example of a non-volatile field-effect transistor using a two-dimensional electron gas,

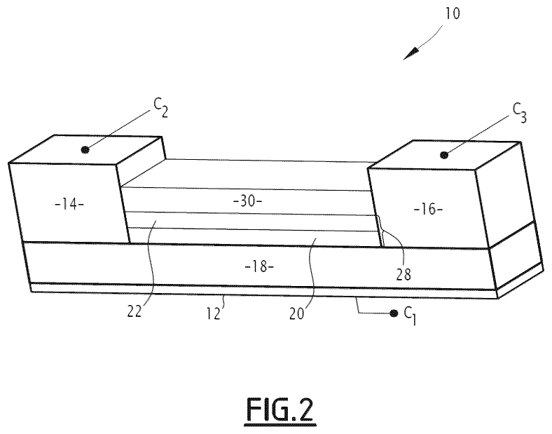

FIG. 2 is a schematic representation of another example of a non-volatile field-effect transistor using a two-dimensional electron gas,

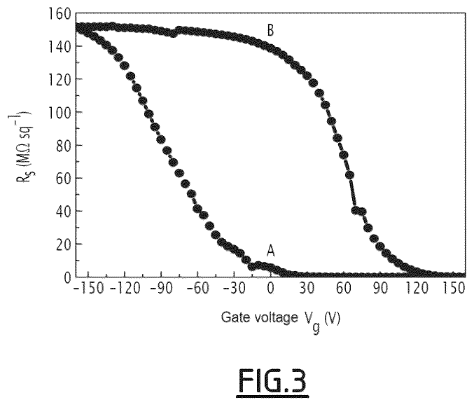

FIG. 3 is a graph showing the dependence of the resistance between two contacts as a function of an applied voltage,

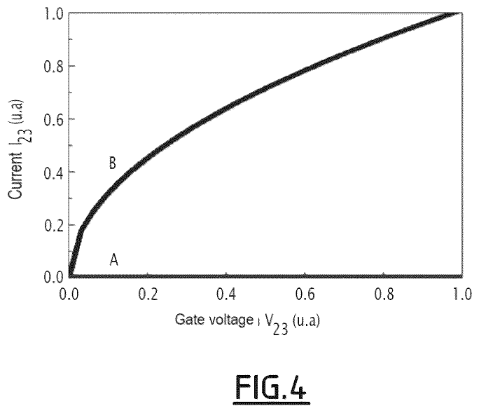

FIG. 4 is a graph illustrating the current-voltage characteristic of an example of transistor in the on and off states, and

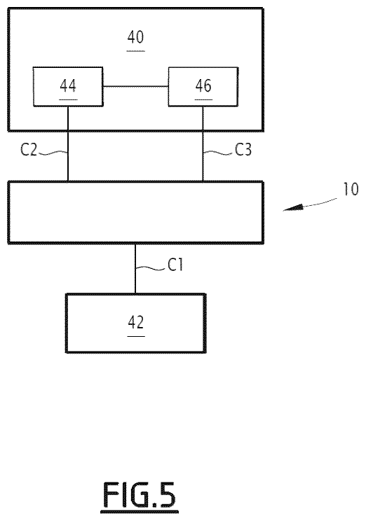

FIG. 5 is a schematic representation of an example of transistor with the read and write units.

A transistor 10 is shown in FIGS. 1 and 2.

The transistor 10 is a non-volatile field-effect transistor.

The transistor 10 includes three electrodes, a first electrode called the gate electrode 12 including a first contact C1, a second electrode 14 called the source 14 and including a second contact C2 and a third electrode 16 called the drain 16 and including a third contact C3.

The electrodes are advantageously metallic or made of highly doped semiconductor material.

The transistor 10 further includes a remanent-state subassembly 18, a channel 20 formed by a two-dimensional electron gas and located between the drain 16 and the source 14, and a reducing layer 22.

As can be seen in FIG. 5, the transistor 10 further includes a read unit 40 and a write unit 42.

The read unit 40 further includes a voltage application sub-unit 44 and a current measuring sub-unit 46.

Two distinct arrangements of the layers of the transistor 10 are proposed in FIG. 1 and in FIG. 2, respectively.

Hereinafter, the layers of a stack are layers stacked along a stacking direction. The relative notions of low and high with respect to the direction of stacking, are also defined. A layer is lower than another layer if same is lower in the representation on the sheet in FIG. 1.

In the example shown in FIG. 1, the non-volatile transistor 10 includes a substrate 24 on which rests the drain 16, the source 14 and a stack 26 of layers, comprising the reducing layer 22, the channel 20 and the remanent-state subassembly 18, stacked in said order when the stack 26 is traversed from the bottom to the top (the bottom corresponding to the substrate in the present case).

Finally, the thickness of a layer is defined as the dimension along the direction of stacking of the layer, i.e. the distance between the two faces thereof.
the gate electrode 12 is in contact with the remanent-state subassembly 18.

The order of the layers of the stack 26 can be reversed as shown in FIG. 2.

In the case of FIG. 2, the remanent-state subassembly 18 rests on the gate electrode 12. The drain 16, the channel 20 and the source 14 rest on the remanent-state subassembly 18.

The channel 20 and the reducing layer 22 form in said order, a stack 28 running through the stack 28 from the bottom to the top.

Furthermore, optionally, the stack 28 includes a protective layer 30 resting on the reducing layer 22.

The protective layer 30 is made of insulating materials, characterized by zero or almost zero conductance, and enabling the stack 28 to be protected, in particular from oxidation.

The protective layer 30 is made e.g. of SiO₂.

In the two cases illustrated, the source 14 and the drain 16 are in contact with a respective end of the channel 20.

The remanent-state subassembly 18 has at least two electrically controllable remanent states. Electrical control is obtained herein by applying a voltage between the first contact C1 and the second or third contacts C2 or C3.

In other words, the remanent-state subassembly 18 is characterized by a non-linear relationship between the applied voltage and the apparent stored charge following a hysteresis cycle and giving rise to at least two remanent states.

For this purpose, the remanent-state subassembly 18 is a dielectric layer or a stack of nonvolatile dielectric layers electrically controlled by the ferroelectric effect, by the trapped charge effect, by the ion migration effect or by a combination of a plurality of said effects. Remanent states correspond to variations of the ferroelectric polarization, of the number of trapped charges, or of the ion positions, or of combinations of such variations.

More precisely, the subassembly includes at least one oxide layer made of a material chosen from perovskite oxides, or oxides based on HfO₂, possibly doped with other elements, such as (Hf₁₋ₓZrₓ)O₂ or (Hf₁₋ₓGaₓ)O₂ (x varying between 0 and 1), or the alloys thereof, or polyvinylidene fluoride.

Perovskite oxides have a structure of the type ABO₃ where A and B are cations. BaTiO₃, PZT (i.e. PbZr₁₋ₓTiₓO₃ with x varying between 0 and 1), PMN-PT (i.e. [1-x]Pb(Mg1/3Nb_{2/3}) O₃-xPbTiO₃ with x varying between 0 and 1), BiFeO₃ (doped, if appropriate, e.g. with rare earth on the Bi site, or with Mn on the Fe site), SrTiO₃ (doped, if appropriate), KTiO₃ (doped, if appropriate), Pr_{0.7}Ca_{0.3}MnO₃ (doped, if appropriate) or YMnO₃ (doped, if appropriate) are examples of such materials.

The use of a dielectric material to produce the remanent-state subassembly 18 serves to electrically control the conductivity of the channel 20 in a non-volatile way.

In each of the preceding examples, the existence of the remanent states comes from a ferroelectric effect, a trapped charge effect, an ion migration effect, or a combination of a plurality of such effects. In practice, the predominant effect depends on the materials and on the conditions of deposition of the layers forming the remanent-state subassembly 18. According to the example described, the coercive electric field of the dielectric element and the thickness thereof are sufficiently small for the write device 14 to be apt to write the remanent states at voltages compatible with microelectronic technologies, i.e. voltages below 10 volts (<10 V). A thickness of less than 100 nm and advantageously less than 50 nm in the aforementioned materials makes it possible to obtain such properties. The remanent-state subassembly 18 is also resistant to cycling, typically apt to withstand at least 10⁴ cycles.

The channel 20 consists of a two-dimensional electron gas, i.e. a confined electron gas which forms at the interface between two layers, whereas there is no gas in the volume of the materials taken separately.

The channel 20 is thus an electron gas forming at the interface between the remanent-state subassembly 18 and the reducing layer 22. Same has a high carrier density (typically greater than or equal to 10¹⁰ cm⁻²). The confinement is such that it can be considered that the gas is strictly two-dimensional since only the vicinity of the interface is conductive.

Since the electron gas of the channel 20 is created at the interface between the remanent-state subassembly 18 and the reducing layer 22, the properties thereof and in particular the resistance thereof depend directly on the state of the remanent-state subassembly 18. The resistance of the two-dimensional electron gas and hence of the channel 20 can thus be electrically modulated in a non-volatile manner according to the state of the remanent-state subassembly 18. It is thereby possible to modulate the resistance of the channel 20 by choosing the remanent state of the remanent-state subassembly 18.

The reducing layer 22 is used to create the two-dimensional electron gas forming the channel at the interface between the reducing layer 22 and the remanent-state subassembly 18.

The reducing layer 22 is made of a reducing material having an atomic concentration of metal elements greater than or equal to 50%, preferably greater than or equal to 80%.

By definition, atomic concentration is the ratio between the number of atoms of metal elements and the total number of atoms.

In this sense, the reducing layer 22 is a reducing layer that can be described as a reducing layer of the metal type.

As a particular example, each metal element of the reducing layer 22 is chosen from Al, Ta, Ru, Pt, W, Ir, Mo, Ti, Y, Au, or an alloy thereof such as PtW.

Other metal elements are conceivable such as Mg, Cr, Mn, Cu, Pd, Ag, Hf, Bi, Co and Fe.

Thereby, each metal element is chosen from the list consisting of Mg, Al, Ti, V, Ni, Cr, Mn, Cu, Mo, Nb, Ru, Rh, Pd, Ag, Hf, Ta, W, Ir, Bi, Co, Y, Pt, W, Au and Fe or an alloy thereof.

Preferably, each metal element is chosen from the list consisting of aluminum, tantalum, yttrium, magnesium and ruthenium.

In a variant, the reducing layer 22 is a multi-layer. In such case, each layer of said multilayer has, again, an atomic concentration of metal elements greater than or equal to 50%, preferably greater than or equal to 80%.

The reducing layer 22 makes possible the formation of the two-dimensional gas of electrons in contact with the remanent-state subassembly 18. In this sense, the channel 20 formed by a two-dimensional electron gas is quite different from the channel of a conventional field-effect transistor, wherein there is no reducing layer. Also, in the channel of a conventional field-effect transistor, the carriers appear reversibly in the semiconductor material (in general made of doped Si), by applying a gate voltage generating an electrostatic field.

The reducing layer 22 has a thickness which is less than or equal to 15 nanometers (nm)

The above allows the reducing layer 22, partially or completely oxidized in contact with the remanent-state subassembly 18, to have a lower conductivity than the conductivity of the two-dimensional electron gas. The thickness of the reducing layer 22 is preferably chosen so that same is completely oxidized by contact with the remanent-state subassembly 18, so that the conductivity thereof is the lowest possible.

As indicated hereinabove, the source 14 and the drain 16 are in contact with a respective end of the channel 20, and thereby electrically connected to each other via the channel 20.

Each of the electrodes 12, 14 and 16 are preferably made of a doped metal conductive or semi-conductive material, so as to have a high conductivity.

The operation of the transistor 10 will be now described with reference to FIGS. 3 to 4.

In a first example of operation, the remanent-state subassembly 18 has two states denoted by A and B.

The above can be seen in particular in FIG. 3, which shows the dependence of the resistance between the second contact C2 and the third contact C3 as a function of the voltage applied between the first contact C1 and the second contact C2 (gate voltage Vg). It is indeed observed that the variation in conductivity of the channel 20 as a function of the gate voltage has a hysteresis, corresponding to the 2 remanent states A and B of the subassembly.

According to such first example of operation, the writing is carried out by the writing unit by applying a voltage between the first contact C1 and the second contact C2.

Writing could also be carried out by replacing the second contact C2 with the third contact C3.

From the physical point of view, the conductivity of the channel 20 is herein modulated in a non-volatile manner according to the remanent state of the remanent-state subassembly 18 by the application of a voltage between the first contact C1 and the second contact C2.

In such example of operation, the application of a negative voltage between the first contact C1 and the second contact C2 initializes the remanent-state subassembly 18 in the remanent state A, resulting in a low conductivity of the channel 20. On the other hand, the application of a positive voltage induces a high conductivity of the channel 20, corresponding to the remanent state B of the remanent-state subassembly 18.

Depending on the material used, the sign of the voltages giving the high and low resistance remanent states can be reversed. Thereby, it may be the application of a positive voltage between the first contact C1 and the second contact C2 which results in a low conductivity remanent state of the channel 20. In such case, it is the application of a negative voltage that will induce a remanent state corresponding to a high conductivity of the channel 20.

In such first example of operation, the reading unit 40 non-destructively reads the remanent state by applying a voltage between the second contact C2 and the third contact C3 using the voltage application sub-unit 44 and measuring the resulting current between the two contacts C2 and C3 by means of the measuring sub-unit 46.

The current-voltage characteristic between the second contact C2 and the third contact C3, which corresponds to the output characteristic of the transistor 10, is thereby controlled by the remanent state of the remanent-state subassembly 18.

Such characteristic is shown in FIG. 4.

In a second example of operation, the voltage application sub-unit 44 applies a voltage between the first contact C1 and the second contact C2 so as to obtain any state of the hysteresis cycle. The conductivity of the channel 20 can take more than two states, and thereby be used to encode analog, non-binary information, such as synaptic weight in a neural network for artificial intelligence.

The transistor 10 which has just been described is a non-volatile field-effect transistor using a two-dimensional electron gas channel 20 at the interface between an oxide layer and a metal-type reducing layer 22. It is the association of an oxide layer of the remanent-state subassembly 18 with the reducing layer 22 which makes it possible to achieve a non-volatile control of the conductivity of the channel 20.

The above makes it possible to avoid using an additional ferroelectric element above the structure, since the combination of the remanent-state subassembly 18 and of the reducing layer 22 creates both the two-dimensional electron gas and the remanent states.

Moreover, the presence of an assembly formed by the oxide layer, the two-dimensional electron gas and the reducing layer 22 makes it possible, compared with the non-volatile field-effect transistors of the prior art, to optimize the conductivity of the channel 20, to obtain a better endurance, and an improved contrast between the on state and the off state. The performances obtained by means of the two-dimensional electron gas channel 20, created by using a reducing layer formed according to conventional microelectronic methods such as cathode sputtering, serve to make the transistor 10 suitable for industrial use.

1-12. (canceled)

13. A non-volatile field-effect transistor, the transistor comprising:
a first electrode called a gate electrode including a first contact,
a second electrode called a source, the source comprising a second contact,
a third electrode called a drain, the drain including a third contact,
a channel between the drain and the source, formed by a two-dimensional electron gas,
a remanent-state subassembly, the remanent-state subassembly having at least two electrically controllable remanent states, the remanent-state subassembly being in contact with the channel, the remanent-state subassembly including at least one oxide layer, and
a reducing layer configured to create the two-dimensional gas forming the channel at an interface between the reducing layer and the remanent-state subassembly, the reducing layer being made of at least one metal-type reducing material, each metal-type reducing material having an atomic concentration of metal elements greater than or equal to 50%,
the first electrode being in contact with the remanent-state subassembly and an application of a voltage between the first contact and a contact amongst the second contact and the third contact leading to a non-volatile modulation of a conductivity of the two-dimensional gas forming the channel.

14. The non-volatile transistor according to claim 13, wherein the reducing layer is a monolayer of metal-type reducing material or a multilayer of metal-type reducing materials, the reducing material or materials each having an atomic concentration of metal elements greater than or equal to 50%.

15. The non-volatile transistor according to claim 13, wherein the remanent-state subassembly comprises at least one non-volatile dielectric layer or multilayer electrically controlled by an effect chosen among a ferroelectric effect, a trapped charge effect, an ion migration effect and a combination of a plurality of the effects.

16. The non-volatile transistor according to claim 13, wherein each metal-type reducing material has an atomic concentration of metal elements greater than or equal to 80%.

17. The non-volatile transistor according to claim 13, wherein each metal element is chosen from a list consisting of Mg, Al, Ti, V, Ni, Cr, Mn, Cu, Mo, Nb, Ru, Rh, Pd, Ag, Hf, Ta, W, Ir, Bi, Co, Y, Pt, W, Au and Fe or an alloy thereof.

18. The non-volatile transistor according to claim 13, wherein each metal element is chosen from a list consisting of aluminum, tantalum, yttrium, magnesium and ruthenium.

19. The non-volatile transistor according to claim 13, wherein the reducing layer has a thickness less than or equal to 15 nanometers.

20. The non-volatile transistor according to claim 19, wherein the reducing layer has a thickness less less than or equal to 10 nanometers.

21. The non-volatile transistor according to claim 13, wherein:
the transistor includes a substrate on which rests the drain, the source and the reducing layer,
the reducing layer, the channel and the remanent-state subassembly form a stack in this order, and
the first electrode rests on the remanent-state subassembly.

22. The non-volatile transistor according to claim 13, wherein:
the remanent-state subassembly rests on the first electrode,
the drain, the channel and the source rest on the remanent-state subassembly, and
the reducing layer is arranged over the channel.

23. The non-volatile transistor of claim 22, further including a protective layer arranged over the reducing layer.

24. The non-volatile transistor according to claim 13, wherein the remanent-state subassembly includes a layer chosen amongst:
an oxide layer made of perovskite oxides,
an oxide layer of (Hf₁₋ₓZrₓ)O₂, x varying between 0 and 1, and
a layer made of poly (vinylidene fluoride).

25. The non-volatile transistor according to claim 13, wherein the transistor includes a read unit, the read unit including a sub-unit for applying a voltage between the drain and the source and a sub-unit for measuring a current between the drain and the source.
